(19) United States
(12) Patent Application Publication
(10) Pub. No.: US 2025/0296126 A1
(43) Pub. Date: Sep. 25, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventors: Michinori IWAO, Kyoto-shi (JP); Yukifumi YOSHIDA, Kyoto-shi (JP); Tomohiro UEMURA, Kyoto-shi (JP); Shoyo MINAMI, Kyoto-shi (JP); Yusuke UEDA, Kyoto-shi (JP)

(21) Appl. No.: 19/066,142

(22) Filed: Feb. 27, 2025

(30) Foreign Application Priority Data
Mar. 19, 2024 (JP) 2024-043337

(51) Int. Cl. B08B 3/14; B01D 71/02; B08B 3/08; B08B 3/10; C02F 1/44; C02F 101/34; H01L 21/67

(52) U.S. Cl. CPC B08B 3/14; B01D 71/0281; B08B 3/08; B08B 3/106; C02F 1/44; B08B 2203/007; C02F 2101/34; H01L 21/67051

(57) ABSTRACT

A substrate processing apparatus includes: a collection tank that stores a mixed fluid containing water supplied to a substrate and then collected and an organic solvent supplied to the substrate and then collected; a circulation pipe connected to the collection tank; a dewaterer disposed in the circulation pipe and including a separation membrane that allows the water to pass through and does not allow the organic solvent to pass through; a pump disposed in the circulation pipe; and a heater disposed downstream of the collection tank and upstream of the dewaterer in the circulation pipe, the heater heating the mixed fluid to a boiling point of the water or higher.

### BACKGROUND

### Technical Field

The present disclosure relates to a substrate processing apparatus and a substrate processing method.

### Description of the Background Art

In substrate processing apparatuses used in manufacturing steps of semiconductor devices, etc., for example, a substrate is processed with a chemical liquid, and then rinsed out with a rinse liquid. In Japanese Patent Application Laid-Open No. 2017-41505, a substrate rinsed out with a rinse liquid (i.e., a substrate covered with a rinse liquid (typically, water)) is supplied with isopropyl alcohol (IPA) to replace the rinse liquid on the substrate with IPA. Then, the substrate is rotated at high speeds to blow off the IPA that adheres to the substrate, and is dried. When rotating the substrate at high speeds to blow off the adhering liquid, there is a risk that the surface tension of the adhering liquid may collapse a pattern. However, previous replacement of the water that adheres to the substrate with IPA with a surface tension lower than that of water suppresses the collapse of the pattern. Since IPA is bipolar, even when the surface of the substrate is hydrophobic, the substrate can evenly become wet. Thus, the dried substrate hardly has watermarks.

Japanese Patent Application Laid-Open No. 2017-41505 describes collecting IPA supplied to the substrate. Since IPA is supplied to the substrate covered with water, collected IPA is diluted with water (i.e., IPA is collected as a mixed solution of IPA and water). Thus, recycling the collected IPA requires separating water from the mixed solution.

In order to separate water from a mixed solution of water and an organic solvent such as IPA, for example, a separation membrane that allows water molecules to pass through and does not allow molecules of an organic solvent to pass through is probably used. In order to reduce the time required for the separation of water, it is necessary to enhance the separation efficiency using the separation membrane.

### SUMMARY

The present disclosure is directed to a substrate processing apparatus. The substrate processing apparatus according to one aspect of the disclosure includes: a rinse liquid supply nozzle that supplies a substrate with a rinse liquid containing water; an organic solvent supply nozzle that supplies an organic solvent to the substrate; a collection tank that stores a mixed fluid containing the water supplied to the substrate and then collected and the organic solvent supplied to the substrate and then collected; a circulation pipe connected to the collection tank; a dewaterer disposed in the circulation pipe and including a separation membrane that allows the water to pass through and does not allow the organic solvent to pass through; a pump disposed in the circulation pipe; and a heater disposed downstream of the collection tank and upstream of the dewaterer in the circulation pipe, the heater heating the mixed fluid to a boiling point of the water or higher.

The present disclosure is also directed to a substrate processing method. The substrate processing method according to one aspect of the disclosure includes: supplying a substrate with a rinse liquid containing water; supplying an organic solvent to the substrate; storing, in a collection tank, a mixed fluid containing the water supplied to the substrate and then collected and the organic solvent supplied to the substrate and then collected; circulating the mixed fluid stored in the collection tank, through a circulation pipe connected to the collection tank; heating the mixed fluid to a boiling point of the water or higher, using a heater disposed in the circulation pipe; and causing the heated mixed fluid to flow into a dewaterer including a separation membrane that allows the water to pass through and does not allow the organic solvent to pass through, and separating the water from the mixed fluid, the dewaterer being disposed downstream of the heater and upstream of the collection tank in the circulation pipe.

Thus, the object of this disclosure is to provide a technology that can enhance the separation efficiency using the separation membrane.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example structure of a substrate processing apparatus;

FIG. 2 is a side view schematically illustrating an example structure of a processing unit;

FIG. 3 schematically illustrates an example structure of an organic solvent collector;

FIG. 4 is a side sectional view schematically illustrating an example structure of a dewaterer;

FIG. 5 illustrates an example procedure to be performed by the organic solvent collector;

FIG. 6 illustrates an example procedure for separating water from a mixed fluid;

FIG. 7 is a diagram for illustrating Step S1;

FIG. 8 is a diagram for illustrating Step S201;

FIG. 9 is a diagram for illustrating Step S203;

FIG. 10 is a diagram for illustrating Step S207;

FIG. 11 is a diagram for illustrating Step S3;

FIG. 12 is a diagram for illustrating Step S4; and

FIG. 13 schematically illustrates an example structure of the organic solvent collector according to a modification.

### DESCRIPTION OF THE PREFERRED EMBODIMENTS

An embodiment will be described below with reference to the attached drawings. The constituent elements described in the embodiment are mere exemplification, and only the exemplification does not intend to limit the scope of the disclosure. The drawings are drawn in schematic form, structures are appropriately omitted or simplified, and the dimensions and the number of parts are illustrated in exaggeration or simplified for convenience in description. The position relationships between the structures in the drawings are not necessarily accurately illustrated.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “homogeneous”) include those indicating quantitatively exact equality and those in the presence of a difference within tolerance or to the extent that similar functions can be obtained. Unless otherwise noted, the expressions indicating shapes (e.g., “circular”, “oval”, “rectangular” or “cylindrical”) include those indicating geometrically exact shapes and those indicating, for example, roughness or a chamfer to the extent that similar advantages can be obtained. An expression “comprising”, “including”, “containing”, or “having” one or more constituent elements is not an exclusive expression for excluding the presence of the other constituent elements. An expression “at least one of A, B, or C” involves “only A”, “only B”, “only C”, “any two of A, B, and C”, and “all of A, B, and C”. Even when the ordinal numbers such as “first” and “second” are used, these terms are used for convenience to facilitate the understanding of the details of the embodiment. The order indicated by these ordinal numbers does not restrict the details of the embodiment.

### 1. SUBSTRATE PROCESSING APPARATUS

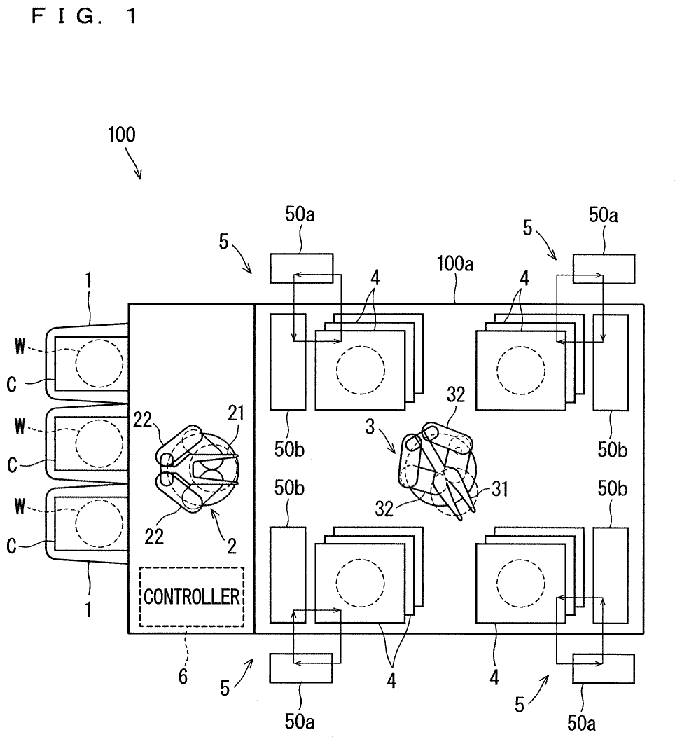

A substrate processing apparatus 100 according to the embodiment will be described with reference to FIG. 1. FIG. 1 is a plan view schematically illustrating an example structure of the substrate processing apparatus 100.

The substrate processing apparatus 100 is a single-wafer processing apparatus that processes (treats) substrates W to be processed one by one. The substrate W to be processed by the substrate processing apparatus 100 is, for example, a semiconductor substrate. The shape of the substrate W to be processed is, for example, disk-shaped.

The substrate processing apparatus 100 includes load ports 1, an indexer robot 2, a main transport robot 3, processing units 4, organic solvent collectors 5, and a controller 6.

Each of the load ports 1 is an interface for transporting the substrate W into and out of a carrier C that is a sort of a container that houses a plurality of the substrates W. The number of the load ports 1 is, for example, multiple (three in the example of the drawing). The load ports 1 are, for example, horizontally aligned in a row. The carriers C may be of a type that houses the substrates W in an airtight space (e.g., a front opening unified pod (FOUP) or a standard mechanical interface (SMIF) pod), or of a type that exposes the substrates W to outside air (e.g., an open cassette (OC)).

The indexer robot 2 is a transporter that transports the substrate W. The indexer robot 2 is, for example, a horizontal articulated robot, and includes a pair of hands 21 that hold the substrate W, and an arm 22 that is connected to each of the hands 21. Furthermore, the indexer robot 2 includes a driving mechanism (not illustrated) for rotating each of the hands 21 and flexing, rotating, and raising and lowering each of the arms 22. The indexer robot 2 transports the substrate W between each of the carriers C placed on the load ports 1 and the main transport robot 3. In other words, the indexer robot 2 accesses each of the carriers C placed on the load ports 1 to perform an unloading operation (i.e., an operation of unloading the substrate W housed in the carrier C using the hands 21) and perform a loading operation (i.e., an operation of loading the substrate W held by the hands 21 into the carrier C). Furthermore, the indexer robot 2 accesses a transfer position to transfer the substrate W to and from the main transport robot 3.

The main transport robot 3 is a transporter that transports the substrate W. The main transport robot 3 is, for example, a horizontal articulated robot, and includes a pair of hands 31 that hold the substrate W, and an arm 32 that is connected to each of the hands 31. Furthermore, the main transport robot 3 includes a driving mechanism (not illustrated) for rotating each of the hands 31 and flexing, rotating, and raising and lowering each of the arms 32. The main transport robot 3 transports the substrate W between the indexer robot 2 and each of the processing units 4. In other words, the main transport robot 3 accesses a transfer position to transfer the substrate W to and from the indexer robot 2. Furthermore, the main transport robot 3 accesses each of the processing units 4 to perform a loading operation (i.e., an operation of loading the substrate W held by the hands 31 into the processing unit 4) and perform an unloading operation (i.e., an operation of unloading the substrate W in the processing unit 4 using the hands 31).

Each of the processing units 4 subjects the substrate W to a predetermined processing using processing liquids (e.g., a chemical liquid, a rinse liquid, and an organic solvent). For example, the plurality of processing units 4 (e.g., three processing units 4) stacked in a vertical direction compose one tower. The plurality of towers (e.g., four towers in the example of the drawing) are placed around the main transport robot 3. The specific structure of the processing unit 4 will be described later.

Each of the organic solvent collectors 5 collects the organic solvent that has been used for the processing in the processing unit 4, and supplies the organic solvent to the processing unit 4 again. Here, the organic solvent collectors 5 as many as the towers are provided. The organic solvent collectors 5 correspond one-to-one with the towers. Each of the organic solvent collectors 5 collects the organic solvent that has been used for the processing in the respective processing units 4 included in the corresponding tower, and supplies the organic solvent to the respective processing units 4 included in the corresponding tower again. The specific structure of the organic solvent collector 5 will be described later.

The controller 6 controls operations of parts included in the substrate processing apparatus 100 (the load ports 1, the indexer robot 2, the main transport robot 3, the processing units 4, and the organic solvent collectors 5). The controller 6 is implemented by, for example, a common computer with an electrical circuit. The controller 6 includes, for example, a central processing unit (CPU) that performs various computation processes (data processes), a read-only memory (ROM) for storing a basic program, etc., a random access memory (RAM) used as a work area when the CPU performs a predetermined process (a data process), a storage device (specifically, for example, non-volatile storage devices such as a flash memory and a hard disk device), and a bus line that mutually connects these. The storage device or the RAM may store a program for defining processes to be executed by the controller 6. Here, for example, the CPU executes the program, so that the controller 6 may control the parts included in the substrate processing apparatus 100 and the substrate processing apparatus 100 may execute the processes defined by the program. In other words, the CPU executes the program, so that the controller 6 may implement a circuit that executes the processes defined by the program. Obviously, hardware such as a dedicated logic circuit may execute (implement) a part or the entire control to be performed by the controller 6 (a part or the entire circuit to be implemented by the controller 6).

### 2. PROCESSING UNIT

### 2-1. Structure of Processing Unit

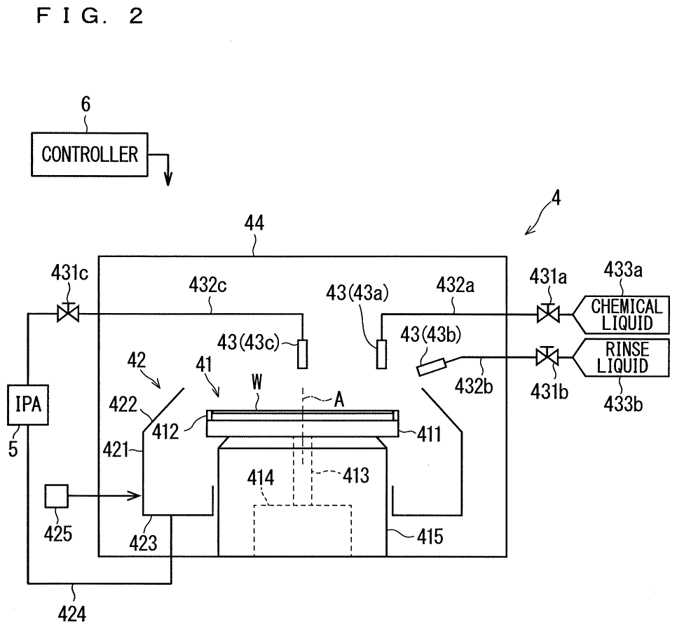

The structure of the processing unit 4 will be described below with reference to FIG. 2. FIG. 2 is a side view schematically illustrating an example structure of the processing unit 4.

Each of the processing units 4 subjects the substrate W to a predetermined processing using processing liquids (e.g., a chemical liquid, a rinse liquid, and an organic solvent). The processing unit 4 includes, for example, a spin chuck 41, a cup 42, and nozzles 43. The spin chuck 41, the cup 42, and the nozzles 43 are housed in a processing chamber 44.

The spin chuck 41 rotates the substrate W about an axis line (a rotation axis line) A that passes through the center of the main surface of the substrate W and extends in the upward and downward direction, while holding the substrate W in a horizontal attitude (an attitude with which the thickness direction of the substrate W is along the upward and downward direction (vertical direction)). The spin chuck 41 includes, specifically for example, a spin base 411. The spin base 411 is a disk-shaped part, and is disposed in an attitude such that the thickness direction is along the upward and downward direction. A plurality of chuck pins 412 are arranged on the upper surface of the spin base 411. The chuck pins 412 are arranged at regular intervals along the circumference corresponding to the outer edge of the substrate W. A linkage mechanism (not illustrated), which moves the chuck pins 412 between an abutment position and an open position, is connected to the chuck pins 412. The abutment position is a position at which the chuck pins 412 abut the outer edge of the substrate W. The open position is a position at which the chuck pins 412 are away from the outer edge of the substrate W. When each of the chuck pins 412 is disposed at the abutment position, the substrate W is held (chucked) in a horizontal attitude above the spin base 411. When each of the chuck pins 412 is disposed at the open position, hold of the substrate W is released. The linkage mechanism switches the positions of the chuck pins 412 according to an instruction from the controller 6. In other words, the controller 6 controls, for example, the timing to hold the substrate W and the timing to release the hold of the substrate W. Furthermore, the spin base 411 is connected to a spin motor 414 through a shaft 413 disposed coaxial with the rotation axis line A. The shaft 413 and the spin motor 414 are housed in a cover 415. The spin motor 414 rotates the shaft 413 about the rotation axis line A. This allows the spin base 411 and further the substrate W held above the spin base 411 to rotate about the rotation axis line A. The spin motor 414 rotates the spin base 411 according to an instruction from the controller 6. In other words, the controller 6 controls, for example, the rotation speed, the rotation start timing, and the rotation end timing of the spin base 411 (further the substrate W).

The cup 42 receives the processing liquid discharged from the substrate W that is held and rotated by the spin chuck 41. The cup 42 specifically includes, for example, a cylindrical guide part 421 disposed coaxial with the rotation axis line A, a slope 422 that is continuous from the upper end of the guide part 421 and has a diameter that becomes smaller toward the top, and a liquid receiver 423 that is continuous from the lower end of the guide part 421 and forms an annular groove that is opened upward. The liquid receiver 423 is equipped with cup-side collecting pipes that collect the liquid received herein. Here, for example, the cup-side collecting pipes include a cup-side collecting pipe for the chemical liquid (not illustrated) and a cup-side collecting pipe 424 for the organic solvent. Furthermore, a cup elevating mechanism 425 that moves the cup 42 up and down between a lower position and an upper position is connected to the cup 42. The lower position is a position at which the upper end of the cup 42 (specifically, the upper end of the slope 422) is located below the substrate W held by the spin chuck 41. The upper position is a position at which the upper end of the cup 42 is located above the substrate W held by the spin chuck 41. The cup elevating mechanism 425 moves the cup 42 up and down according to an instruction from the controller 6. In other words, the controller 6 controls the position of the cup 42.

The nozzles 43 each discharge (dispense) a processing liquid toward the upper surface of the substrate W held by the spin chuck 41. Here, for example, the nozzles 43 are separately provided for each type of processing liquids. In other words, the nozzles 43 include the nozzle 43 for discharging a chemical liquid (also hereinafter referred to as a “chemical liquid nozzle 43a”), the nozzle 43 for discharging a rinse liquid (also hereinafter referred to as a “rinse liquid nozzle 43b”), and the nozzle 43 for discharging an organic solvent (also hereinafter referred to as an “organic solvent nozzle 43c”).

The chemical liquid nozzle 43a discharges a chemical liquid toward the upper surface of the substrate W held by the spin chuck 41. The chemical liquid nozzle 43a is connected to a chemical liquid supply source 433a through a chemical liquid pipe 432a into which a chemical liquid valve 431a is inserted. Once the chemical liquid valve 431a is opened, a chemical liquid is supplied to the chemical liquid nozzle 43a through the chemical liquid pipe 432a, and the chemical liquid is discharged from the chemical liquid nozzle 43a. The chemical liquid valve 431a is opened and closed according to an instruction from the controller 6. In other words, the controller 6 controls the timing to discharge the chemical liquid from the chemical liquid nozzle 43a. The chemical liquid is, for example, fluoric acid. The chemical liquid is not limited to fluoric acid, but may be at least one of sulfuric acid, acetic acid, nitric acid, hydrochloric acid, hydrofluoric acid, phosphoric acid, ammonia water, a hydrogen peroxide solution, organic acid (e.g., citric acid and oxalic acid), organic alkali (e.g. tetramethylammonium hydroxide (TMAH)), a surface active agent, or a corrosion inhibitor.

The rinse liquid nozzle 43b discharges a rinse liquid toward the upper surface of the substrate W held by the spin chuck 41. In other words, the rinse liquid nozzle 43b functions as a rinse liquid supply nozzle (a rinse liquid supply part) that supplies a rinse liquid to the substrate W herein. The rinse liquid nozzle 43b is connected to a rinse liquid supply source 433b through a rinse liquid pipe 432b into which a rinse liquid valve 431b is inserted. Once the rinse liquid valve 431b is opened, a rinse liquid is supplied to the rinse liquid nozzle 43b through the rinse liquid pipe 432b, and the rinse liquid is discharged from the rinse liquid nozzle 43b. The rinse liquid valve 431b is opened and closed according to an instruction from the controller 6. In other words, the controller 6 controls the timing to discharge the rinse liquid from the rinse liquid nozzle 43b. Here, the rinse liquid is water (specifically, for example, pure water (deionized water)).

The organic solvent nozzle 43c discharges an organic solvent toward the upper surface of the substrate W held by the spin chuck 41. In other words, the organic solvent nozzle 43c functions as an organic solvent supply nozzle (an organic solvent supply part) that supplies an organic solvent to the substrate W herein. The organic solvent nozzle 43c is connected to the organic solvent collector 5 through an organic solvent pipe 432c into which an organic solvent valve 431c is inserted. Once the organic solvent valve 431c is opened, an organic solvent (an organic solvent with sufficiently high purity, specifically, for example, an organic solvent with purity of 99 wt % or higher) is supplied to the organic solvent nozzle 43c through the organic solvent pipe 432c, and is discharged from the organic solvent nozzle 43c. The organic solvent valve 431c is opened and closed according to an instruction from the controller 6. In other words, the controller 6 controls the timing to discharge the organic solvent from the organic solvent nozzle 43c. The organic solvent is, for example, a water-soluble organic solvent. Here, the organic solvent is isopropyl alcohol (IPA).

A nozzle movement mechanism that moves at least one of the chemical liquid nozzle 43a, the rinse liquid nozzle 43b, or the organic solvent nozzle 43c between a processing position and a retracted position may be connected to the at least one nozzle. The processing position is a position at which the processing liquid discharged from the nozzle 43a, 43b, or 43c is supplied to the substrate W held by the spin chuck 41. The retracted position is a position of the nozzle 43a, 43b, or 43c that is located outside of the outer edge of the substrate W held by the spin chuck 41 (outward in a radial direction) when viewed from the top. Here, the nozzle movement mechanism moves the nozzle 43a, 43b, or 43c according to an instruction from the controller 6. In other words, the controller 6 controls the positions of the nozzle 43a, 43b, and 43c.

### 2-2. Operations of Processing Unit

Example operations of the processing unit 4 will be described with reference to FIG. 2 again.

The operations of the processing unit 4 are performed under control of the controller 6. In other words, the controller 6 controls, for example, the chuck pins 412, the spin motor 414, the cup elevating mechanism 425, the chemical liquid valve 431a, the rinse liquid valve 431b, and the organic solvent valve 431c, so that the processing unit 4 proceeds with a series of the operations.

Once the main transport robot 3 transports the substrate W into the processing chamber 44, the spin chuck 41 holds the substrate W. Then, the spin chuck 41 starts rotating.

In this state, the chemical liquid valve 431a is opened. Then, the chemical liquid nozzle 43a discharges the chemical liquid toward the upper surface of the substrate W held and rotated by the spin chuck 41. This supplies the chemical liquid to the entire region of the upper surface of the substrate W to process the substrate W with the chemical liquid (a chemical liquid supplying step). For example, when fluoric acid is used as the chemical liquid, the chemical liquid removes a foreign substance such as particles from the substrate W. During the chemical liquid supplying step, the cup 42 is located at the upper position. Thus, the cup 42 receives the chemical liquid scattered around the substrate W. In other words, the chemical liquid scattered around the substrate W is received by the slope 422, is guided downward by the guide part 421, and is collected by the liquid receiver 423. The chemical liquid received by the cup 42 (i.e., the chemical liquid collected by the liquid receiver 423) is collected through the cup-side collecting pipe (not illustrated) for the chemical liquid.

After a lapse of a predetermined time since start of discharging the chemical liquid, the chemical liquid valve 431a is closed. Then, the chemical liquid nozzle 43a stops discharging the chemical liquid. Next, the rinse liquid valve 431b is opened. Then, the rinse liquid nozzle 43b discharges the rinse liquid toward the upper surface of the substrate W held and rotated by the spin chuck 41. This supplies the rinse liquid to the entire region of the upper surface of the substrate W to rinse out the chemical liquid that adheres to the substrate W with the rinse liquid (a rinse liquid supplying step). During the rinse liquid supplying step, the cup 42 is also located at the upper position. Thus, the cup 42 receives the chemical liquid and the rinse liquid scattered around the substrate W. The chemical liquid and the rinse liquid received by the cup 42 are collected through the cup-side collecting pipe (not illustrated) for the chemical liquid.

After a lapse of a predetermined time since start of discharging the rinse liquid, the rinse liquid valve 431b is closed. Then, the rinse liquid nozzle 43b stops discharging the rinse liquid. Next, the organic solvent valve 431c is opened. Then, the organic solvent nozzle 43c discharges IPA toward the upper surface of the substrate W held and rotated by the spin chuck 41. This supplies IPA to the entire region of the upper surface of the substrate W to replace the rinse liquid that adheres to the substrate W with IPA (an organic solvent supplying step). During the organic solvent supplying step, the cup 42 is also located at the upper position. Thus, the cup 42 receives the rinse liquid and the IPA scattered around the substrate W. The rinse liquid and the IPA received by the cup 42 are collected through the cup-side collecting pipe 424 for the organic solvent.

After a lapse of a predetermined time since start of supplying IPA, the organic solvent valve 431c is closed. Then, the organic solvent nozzle 43c stops discharging IPA. In this phase, the rinse liquid on the substrate W is completely replaced with IPA, and a liquid film of IPA covering the entire region of the upper surface of the substrate W is formed. Next, the spin chuck 41 starts rotating at high speeds. This allows the substrate W to rotate at high speeds to throw off the IPA on the substrate W around the substrate W by centrifugal force (a spin drying step). While the substrate W is rotated at high speeds, the cup 42 is also located at the upper position. Thus, the cup 42 receives the IPA scattered around the substrate W. The IPA received by the cup 42 is collected through the cup-side collecting pipe 424 for the organic solvent.

After a lapse of a predetermined time since the spin chuck 41 starts rotating at high speeds, the rotation of the spin chuck 41 is stopped. In this phase, the IPA is removed from the substrate W, and the substrate W is dried. The main transport robot 3 transports the dried substrate W out of the processing chamber 44.

As described above, a series of processes on the single substrate W is completed. In the processing unit 4, the aforementioned series of processes is repeated to process the substrates W one by one.

### 3. ORGANIC SOLVENT COLLECTOR

### 3-1. Structure

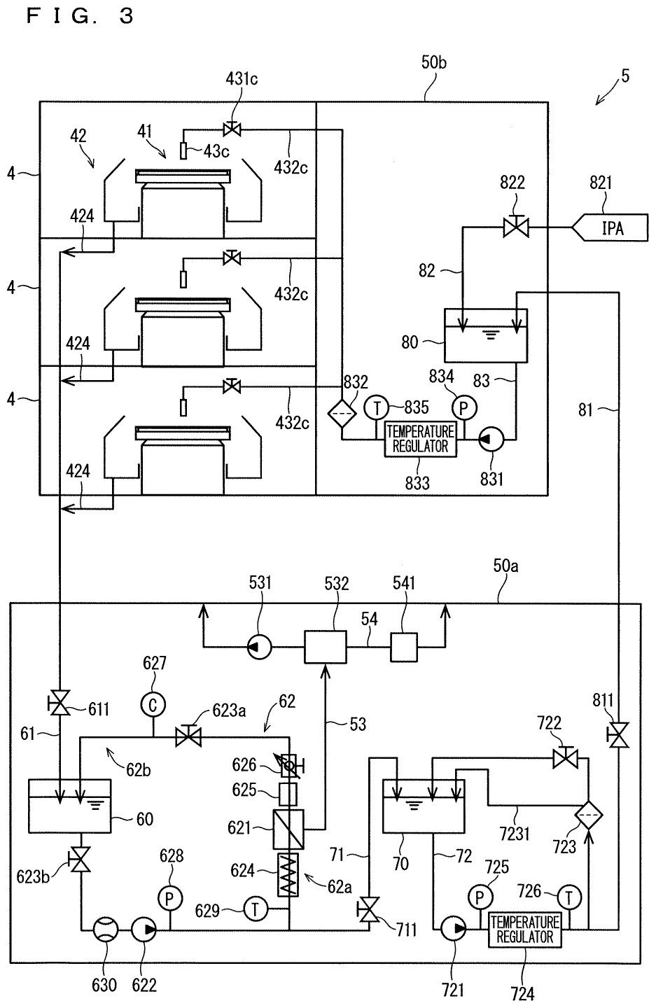

The structure of the organic solvent collector 5 will be described with reference to FIG. 3. FIG. 3 schematically illustrates an example structure of the organic solvent collector 5.

The organic solvent collector 5 includes a collection tank 60, a purification tank 70, and a supply tank 80. For example, a first storage box 50a houses the collection tank 60 and the purification tank 70, and a second storage box 50b houses the supply tank 80. For example, the first storage box 50a is disposed outside an external wall 100a of the substrate processing apparatus 100 (e.g., under a clean room in which the substrate processing apparatus 100 is installed (underground)), and the second storage box 50b is disposed inside the external wall 100a of the substrate processing apparatus 100 (FIG. 1).

### (a) Collection Tank 60

The collection tank 60 is connected to the cups 42 through a collection pipe 61. In other words, one end of the collection pipe 61 is connected to the collection tank 60, and the other end of the collection pipe 61 is connected to the cups 42 (specifically, the cup-side collecting pipes 424 connected to the cups 42). Here, for example, the collection pipe 61 is connected to the cup 42 included in each of the processing units 4 belonging to the same tower. A collection valve 611 is disposed in the collection pipe 61. Once the collection valve 611 is opened, the organic solvent (IPA herein) collected by the cups 42 in the organic solvent supplying step and the spin drying step is guided by the collection pipe 61, and flows into and is stored by the collection tank 60. The IPA (IPA with sufficiently high purity, specifically, for example, IPA with purity of 99 wt % or higher) is collected in the spin drying step, whereas IPA in a state where the IPA is mixed with the rinse liquid (water herein) (i.e., a state of being diluted with water) is collected in the organic solvent supplying step. Thus, the collection tank 60 stores a mixed fluid containing the water supplied to the substrate W and then collected in the processing unit 4 and the IPA supplied to the substrate W and then collected in the processing unit 4.

A circulation pipe (a dewatering circulation pipe) 62 is connected to the collection tank 60. Specifically, both of one end and the other end of the dewatering circulation pipe 62 are connected to the collection tank 60. The dewatering circulation pipe 62 forms a circulation path through which the mixed fluid stored in the collection tank 60 circulates by flowing out of the collection tank 60 and returning to the collection tank 60 again.

A dewaterer (separator) 621 is disposed in the dewatering circulation pipe 62. The dewaterer 621 separates water from the mixed fluid flowing into the dewaterer 621 to dewater the mixed fluid. The structure of the dewaterer 621 will be described later.

A pump (a dewatering feed pump) 622 and a pair of open/close valves 623a and 623b are disposed in the dewatering circulation pipe 62. For example, the dewatering feed pump 622 is disposed downstream of the collection tank 60 and upstream of the dewaterer 621. The one open/close valve 623a is disposed upstream of the collection tank 60, and the other open/close valve 623b is disposed downstream of the collection tank 60. The dewatering feed pump 622 feeds the mixed fluid in the dewatering circulation pipe 62 at a pressure necessary for circulation (a circulation pressure). The dewatering feed pump 622 feeds the mixed fluid at the circulation pressure with the pair of open/close valves 623a and 623b being opened, so that the mixed fluid stored in the collection tank 60 circulates through the dewatering circulation pipe 62.

A heater 624 is disposed in the dewatering circulation pipe 62. The heater 624 is disposed downstream of the collection tank 60 and upstream of the dewaterer 621. In the example of the drawing, the heater 624 is disposed downstream of the dewatering feed pump 622. The heater 624 heats the mixed fluid to a predetermined temperature (a heating temperature) T1. Here, the heating temperature T1 is a temperature higher than or equal to the boiling point of water. In other words, the heater 624 heats the mixed fluid to the boiling point of water or higher. Here, the boiling point of water is strictly the boiling point of water at the circulation pressure. Since the circulation pressure is sufficiently low, the boiling point of water at the circulation pressure can be regarded as being identical to the boiling point of water (100° C.) at atmospheric pressure. The specific structure of the heater 624 may be any. For example, the heater 624 may include a structure that covers a periphery of a pipe and heats a fluid flowing through the pipe (i.e., a jacket heater). When the heater 624 includes a jacket heater, even an increase in the pressure in the mixed fluid in the pipe by the heating hardly influences operations of the heater 624. When the heater 624 includes a jacket heater, for example, that covers the periphery of a pipe made of a metal with superior thermal conductivity, the mixed fluid in the pipe can be effectively heated.

A cooler 625 is disposed in the dewatering circulation pipe 62. The cooler 625 is disposed downstream of the dewaterer 621 and upstream of the collection tank 60. The cooler 625 cools the mixed fluid to a predetermined temperature (a cooling temperature) T2. Here, the cooling temperature T2 is a temperature lower than a boiling point of an organic solvent (IPA herein). In other words, the cooler 625 cools the mixed fluid to a temperature lower than the boiling point of the organic solvent. Here, the boiling point of the organic solvent is strictly the boiling point of the organic solvent at the circulation pressure. Since the circulation pressure is sufficiently low as described above, the boiling point of the organic solvent at the circulation pressure can be regarded as being identical to the boiling point of the organic solvent (82.3° C. when the organic solvent is IPA) at atmospheric pressure. The specific structure of the cooler 625 may be any. For example, the cooler 625 may be formed using a device (i.e., a heat exchanger) including a cooling pipe which is disposed around a pipe and through which a cooling medium is distributed to remove heat of a fluid flowing through the pipe and cool the fluid.

As described above, the heater 624 heats the mixed fluid to the heating temperature T1 higher than or equal to the boiling point of water. The cooler 625 cools the mixed fluid to the cooling temperature T2 lower than the boiling point of IPA. Thus, the mixed fluid circulates through the dewatering circulation pipe 62 while changing the state. In other words, the mixed fluid circulating through the dewatering circulation pipe 62 is in the vapor state (i.e., the water and the IPA contained in the mixed fluid are both in the vapor state) while the mixed fluid flows through a first pipe (a first piping portion) that is downstream of the heater 624 and upstream of the cooler 625 (hereinafter referred to as a “first piping portion 62a”). And the mixed fluid circulating through the dewatering circulation pipe 62 is in the liquid state (i.e., the water and the IPA contained in the mixed fluid are both in the liquid state) while the mixed fluid flows through a second pipe (a second piping portion) that is downstream of the cooler 625 and upstream of the heater 624 (hereinafter referred to as a “second piping portion 62b”).

Thus, the first piping portion 62a, the devices disposed in the first piping portion 62a (e.g., the dewaterer 621), the heater 624, and the cooler 625 have pressure resistance enough to withstand the pressure of the mixed fluid in the vapor state, and have heat resistance that can withstand the heating temperature T1. In contrast, the second piping portion 62b and the devices disposed in the second piping portion 62b (e.g., the collection tank 60, the dewatering feed pump 622, and the pair of open/close valves 623a and 623b) need not have pressure resistance enough to withstand the pressure of the mixed fluid in the vapor state and heat resistance that can withstand the heating temperature T1. In other words, the second piping portion 62b and the devices disposed in the second piping portion 62b may be lower in pressure resistance and heat resistance than the first piping portion 62a and the devices disposed in the first piping portion 62a. For example, the first piping portion 62a is formed using a pressure-resistance pipe (e.g., a metal pipe), and the second piping portion 62b is formed using a pipe that is not a pressure-resistance pipe (e.g., a resin pipe). Furthermore, the collection tank 60 need not be a pressure vessel (a pressure tank), and is, for example, an atmospheric pressure tank.

Here, the heater 624 and the cooler 625 are disposed in the same dewatering circulation pipe 62. Thus, the mixed fluid cooled to the cooling temperature T2 flows into the heater 624, and the mixed fluid heated to the heating temperature T1 flows into the cooler 625. In other words, the heater 624 needs to increase the temperature of the mixed fluid from the cooling temperature T2 to the heating temperature T1, and the cooler 625 needs to lower the temperature of the mixed fluid from the heating temperature T1 to the cooling temperature T2. To reduce the loads of the heater 624 and the cooler 625, a difference between the heating temperature T1 and the cooling temperature T2 is preferably smaller. In other words, the heating temperature T1 is preferably as low as possible in a range of temperatures higher than or equal to the boiling point of water. For example, the heating temperature T1 is a temperature approximately higher than the boiling point of water by 5 to 10° C. (i.e., 105 to 110° C.). Furthermore, the cooling temperature T2 is preferably as high as possible in a range of temperatures lower than a boiling point of an organic solvent (IPA herein). For example, the cooling temperature T2 is a temperature lower than the boiling point of IPA and higher than room temperature. Particularly, the cooling temperature T2 is a temperature approximately lower than the boiling point of IPA by 5 to 10° C. (i.e., 77.3 to 72.3° C.).

A pressure reducer 626 may be further disposed in the dewatering circulation pipe 62. The pressure reducer 626 is disposed, for example, downstream of the cooler 625 and upstream of the collection tank 60, and reduces the pressure of the mixed fluid cooled by the cooler 625. The pressure reducer 626 may, for example, reduce a value of the pressure of the mixed fluid flowing out from the secondary side relative to that of the mixed fluid flowing in from the primary side by narrowing a flow path to cause a pressure loss in the fluid flowing through a pipe. The pressure reducer 626 can include, for example, a metering valve (a throttle valve), a relief valve (a pressure relief valve), or a pressure-reducing valve (a pressure reducing valve). By providing the pressure reducer 626, the pressure applied to a piping portion (a pipe) downstream of the pressure reducer 626 in the second piping portion 62b, and the devices disposed in the piping portion (e.g., the collection tank 60, the dewatering feed pump 622, and the pair of open/close valves 623a and 623b) can be sufficiently reduced.

Various sensors may be disposed in the dewatering circulation pipe 62. For example, a concentration sensor 627 that measures the concentration of IPA contained in the mixed fluid that circulates through the dewatering circulation pipe 62, a pressure sensor 628 that detects the pressure of the mixed fluid that circulates through the dewatering circulation pipe 62, a temperature sensor 629 that detects the temperature of the mixed fluid that circulates through the dewatering circulation pipe 62, and a flow rate sensor (flowmeter) 630 that measures the flow rate of the mixed fluid that circulates through the dewatering circulation pipe 62 may be disposed in the dewatering circulation pipe 62. Each of the sensors 627, 628, 629, and 630 are preferably disposed in the second piping portion 62b. In the example of the drawing, the concentration sensor 627 is disposed downstream of the pressure reducer 626 and upstream of the collection tank 60, the pressure sensor 628 is disposed in the vicinity downstream of the dewatering feed pump 622, the temperature sensor 629 is disposed in the vicinity upstream of the heater 624, and a flow rate sensor 630 is disposed in the vicinity upstream of the dewatering feed pump 622.

### (b) Dewaterer 621

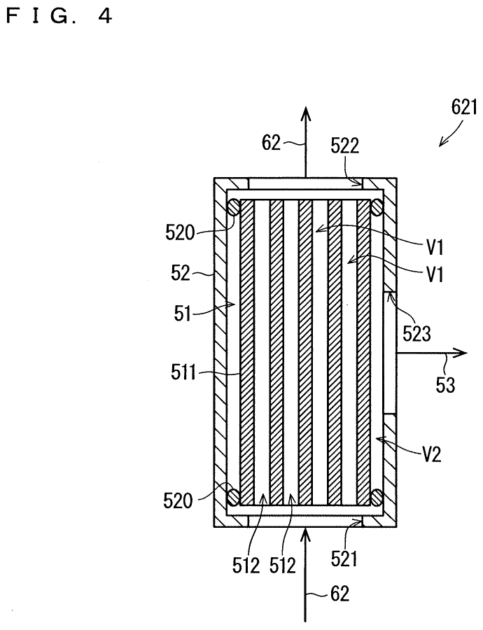

Next, the dewaterer 621 will be described with reference to FIG. 4 in addition to FIG. 3. FIG. 4 is a side sectional view schematically illustrating an example structure of the dewaterer 621.

The dewaterer 621 includes a separation membrane 51 and a housing 52.

The separation membrane 51 is a membrane that allows water to pass through and does not allow an organic solvent (IPA herein) to pass through (the separation membrane 51 blocks the passage of the organic solvent). The separation membrane 51 is, specifically for example, a zeolite membrane made of zeolite. Zeolite has, for example, a crystal structure in which base units of a tetrahedral structure (e.g., base units each including at least one of (SiO₄)⁴⁻ or (AlO₄)⁵⁻) are mutually coupled. The separation membrane 51 has, specifically for example, a structure including a myriad of cells 512 penetrating a cylindrical base body 511 in an axis direction. The cells 512 form the flow paths of the mixed fluid in the separation membrane 51. The entire base body 511 may be made of zeolite or only the inner circumferential surface of each of the cells 512 may be made of zeolite.

The housing 52 is a hollow and cylindrical component, and houses the separation membrane 51 inside. A pair of sealants 520 which seals a portion between the housing 52 and the separation membrane 51 housed in the housing 52 is provided between the housing 52 and the separation membrane 51. Each of the pairs of sealants 520 is, for example, ring-shaped, and is disposed at one end and the other end of the separation membrane 51 in the axis direction. The internal space of the housing 52 is separated by the separation membrane 51 into a cell internal space V1 that is an internal space of the separation membrane 51 (i.e., an internal space of the cells 512), and a separation space V2 that is an external space of the separation membrane 51. Furthermore, the housing 52 has an inlet 521, a first outlet 522, and a second outlet 523. The inlet 521 is disposed at one end face of the housing 52 in the axis direction, and communicates with the cell internal space V1 through one opening of each of the cells 512. The first outlet 522 is disposed at the other end face of the housing 52 in the axis direction, and communicates with the cell internal space V1 through the other opening of each of the cells 512. The second outlet 523 is disposed at the side surface (a peripheral surface) of the housing 52, and communicates with the separation space V2.

The dewatering circulation pipe 62 is connected to the inlet 521 and the first outlet 522. A separation pipe 53 equipped with a vacuum pump 531 is connected to the second outlet 523. The mixed fluid flowing through the dewatering circulation pipe 62 flows from the inlet 521 into the dewaterer 621 (specifically, the cell internal space V1) and flows through the cell internal space V1. Once the vacuum pump 531 disposed in the separation pipe 53 operates in this state, the pressure in the separation space V2 is reduced to provide a pressure difference between the cell internal space V1 and the separation space V2. The separation membrane 51 that separates the cell internal space V1 from the separation space V2 is a membrane that allows water to pass through and does not allow IPA to pass through. Thus, when the pressure difference is provided between the cell internal space V1 and the separation space V2, water (water molecules) contained in the mixed fluid flowing into the cell internal space V1 passes through the separation membrane 51, reaches the separation space V2, and flows into the separation pipe 53 through the second outlet 523. In this manner, water is separated from the mixed fluid. In contrast, since IPA (IPA molecules) contained in the mixed fluid flowing into the cell internal space V1 cannot pass through the separation membrane 51, the IPA flows through the cell internal space V1, and flows into the dewatering circulation pipe 62 through the first outlet 522. As such, the mixed fluid containing the IPA with a concentration higher than that when entering the dewaterer 621 flows out of the dewaterer 621. Each time the mixed fluid repeatedly passes through the dewaterer 621, the concentration of the IPA in the mixed fluid increases.

Here, the heater 624 disposed upstream of the dewaterer 621 heats the mixed fluid to the heating temperature T1 higher than or equal to the boiling point of water. Thus, the mixed fluid flowing into the dewaterer 621 is in the vapor state (i.e., water and IPA contained in the mixed fluid are both in the vapor state). Compared to water in the liquid state, water in the vapor state (steam) has a greater distance between molecules, a smaller force acting between the molecules, and a higher average kinetic energy of the molecules. Therefore, water in the vapor state (steam) passes through the separation membrane 51 more easily than water in the liquid state. Thus, the separation efficiency (dewatering efficiency) is enhanced by the vapor state of the water contained in the mixed fluid flowing into the dewaterer 621. A method of supplying the separation membrane 51 with a fluid to be separated in the vapor state is referred to as, for example, a vapor permeation (VP) method.

A structure on the separation pipe 53 side into which water separated from the mixed fluid flows can be appropriately defined. Here, for example, a condenser 532 is disposed upstream of the vacuum pump 531 in the separation pipe 53. A waste pipe 54 guiding the water condensed by the condenser 532 is connected to the condenser 532. The waste pipe 54 is equipped with a decomposer 541 that decomposes the organic solvent (IPA herein) contained in trace amounts in water flowing through the waste pipe 54 to increase the purity of water. The decomposer 541 may increase the purity of water, for example, through electrolysis of IPA contained in water. The decomposer 541 herein can include, for example, a tank that temporarily stores water flowing through the waste pipe 54, a pair of electrodes to be soaked in the water stored in the tank, and a power supply part that supplies power to the pair of electrodes to produce a potential difference between the electrodes. The waste pipe 54 may be connected to, for example, the rinse liquid supply source 433b (FIG. 2) of the processing unit 4 or a water collection line in a factory. For example, when the waste pipe 54 is connected to the rinse liquid supply source 433b, the water separated from the mixed fluid and flowing into the separation pipe 53 is condensed by the condenser 532 and flows into the waste pipe 54. The water that flows into the waste pipe 54 increases its purity at the decomposer 541, and the water is guided through the waste pipe 54 to the rinse liquid supply source 433b and discharged from the rinse liquid nozzle 43b as a rinse liquid. In other words, the water separated from the mixed fluid is recycled as a rinse liquid herein.

### (c) Purification Tank 70

FIG. 3 is again referred to. The purification tank 70 is connected to the collection tank 60 through a first feed pipe 71 and the dewatering circulation pipe 62. In other words, one end of the first feed pipe 71 is connected to the purification tank 70, and the other end of the first feed pipe 71 is connected to the dewatering circulation pipe 62. For example, the other end of the first feed pipe 71 is connected to the second piping portion 62b of the dewatering circulation pipe 62 (e.g., at a position upstream of the heater 624 and downstream of the dewatering feed pump 622). However, the other end of the first feed pipe 71 may be directly connected to the collection tank 60, not through the dewatering circulation pipe 62. A first feed valve 711 is disposed in the first feed pipe 71. When the collection tank 60 stores a fluid in which the concentration (purity) of IPA has been sufficiently increased (the concentration of IPA is high enough to be supplied to the substrate W) (hereinafter also referred to as a “concentrated fluid”) by separating water from the mixed fluid, once the first feed valve 711 is opened, the concentrated fluid is guided by the first feed pipe 71, and flows into and is stored by the purification tank 70.

A circulation pipe (a purifying circulation pipe) 72 is connected to the purification tank 70. Specifically, both of one end and the other end of the purifying circulation pipe 72 are connected to the purification tank 70. The purifying circulation pipe 72 forms a circulation path through which the concentrated fluid stored in the purification tank 70 circulates by flowing out of the purification tank 70 and returning to the purification tank 70 again.

A pump (a purifying feed pump) 721, and an open/close valve 722 are disposed in the purifying circulation pipe 72. For example, the open/close valve 722 is disposed downstream of the purifying feed pump 721 and upstream of the purification tank 70. The purifying feed pump 721 feeds the concentrated fluid in the purifying circulation pipe 72 at a pressure necessary for circulation. The purifying feed pump 721 feeds the concentrated fluid at the pressure necessary for circulation with the open/close valve 722 being opened, so that the concentrated fluid stored in the purification tank 70 circulates through the purifying circulation pipe 72.

A filter 723 and a temperature regulator 724 are disposed in the purifying circulation pipe 72. For example, the filter 723 is disposed downstream of the purifying feed pump 721 and upstream of the purification tank 70. The temperature regulator 724 is disposed downstream of the purifying feed pump 721 and upstream of the filter 723. The filter 723 captures a removal target substance (e.g., particles and a metal) contained in the concentrated fluid flowing through the purifying circulation pipe 72. Passage of the concentrated fluid through the filter 723 removes the removal target substance contained in the concentrated fluid from the concentrated fluid, and increases the cleanliness of the concentrated fluid. An air removal pipe 7231 may be connected to the filter 723. The temperature regulator 724 is a device with a cooling capacity and a heating capacity, and is, for example, an electronic cooler/heater that electronically cools and heats an object using a Peltier element. When a fluid at a high temperature passes through the filter 723, for example, thermal expansion may cause a decrease in the performance of the filter 723. Thus, the temperature regulator 724 herein cools the concentrated fluid circulating through the purifying circulation pipe 72 to a predetermined temperature (e. g., room temperature) as necessary. This suppresses the decrease in the performance of the filter 723.

Various sensors may be disposed in the purifying circulation pipe 72. For example, a pressure sensor 725 that detects a pressure of the concentrated fluid circulating through the purifying circulation pipe 72, a temperature sensor 726 that detects the temperature of the concentrated fluid circulating through the purifying circulation pipe 72, and a particle counter (not illustrated) that counts the number of particles contained in the concentrated fluid circulating through the purifying circulation pipe 72 may be disposed in the purifying circulation pipe 72. In the example of the drawing, the pressure sensor 725 is disposed in the vicinity downstream of the purifying feed pump 721, and the temperature sensor 726 is disposed in the vicinity downstream of the temperature regulator 724.

### (d) Supply Tank 80

The supply tank 80 is connected to the purification tank 70 through a second feed pipe 81 and the purifying circulation pipe 72. In other words, one end of the second feed pipe 81 is connected to the supply tank 80, and the other end of the second feed pipe 81 is connected to the purifying circulation pipe 72. For example, the other end of the second feed pipe 81 is connected to a position upstream of the filter 723 and downstream of the purifying feed pump 721 in the purifying circulation pipe 72. However, the other end of the second feed pipe 81 may be directly connected to the purification tank 70, not through the purifying circulation pipe 72. A second feed valve 811 is disposed in the second feed pipe 81. When the purification tank 70 stores the concentrated fluid in which the cleanliness has been sufficiently increased (the cleanliness is high enough to be supplied to the substrate W) (hereinafter also referred to as a “purified fluid”), once the second feed valve 811 is opened, the purified fluid is guided by the second feed pipe 81, and flows into and is stored by the supply tank 80.

The supply tank 80 may be connected to a new liquid supply source 821 through a new liquid pipe 82. Here, one end of the new liquid pipe 82 is connected to the supply tank 80, and the other end of the new liquid pipe 82 is connected to the new liquid supply source 821. The new liquid supply source 821 is a supply source of unused IPA that has not yet been supplied to the substrate W (IPA with sufficiently high purity, specifically for example, IPA with purity of 99 wt % or higher). A new liquid valve 822 is disposed in the new liquid pipe 82. Once the new liquid valve 822 is opened, the unused IPA is guided by the new liquid pipe 82, and flows into and is stored by the supply tank 80.

The supply tank 80 is connected to the organic solvent nozzles 43c through a third feed pipe 83. In other words, one end of the third feed pipe 83 is connected to the supply tank 80, and the other end of the third feed pipe 83 is connected to the organic solvent nozzles 43c (specifically, the organic solvent pipes 432c connected to the organic solvent nozzles 43c). Here, for example, the third feed pipe 83 is connected to the organic solvent nozzles 43c included in each of the processing units 4 belonging to the same tower. A pump (a supplying feed pump) 831 is disposed in the third feed pipe 83. Once the organic solvent valves 431c are opened, the purified fluid stored in the supply tank 80 is fed by the supplying feed pump 831 to the organic solvent nozzles 43c side, and is discharged from the organic solvent nozzles 43c.

A filter 832 and a temperature regulator 833 may be disposed in the third feed pipe 83. The filter 832 captures a removal target substance contained in the purified fluid fed through the third feed pipe 83. The temperature regulator 833 regulates the temperature of the purified fluid fed through the third feed pipe 83 (i.e., heats or cools the purified fluid to a predetermined temperature). In the example of the drawing, the temperature regulator 833 is disposed downstream of the supplying feed pump 831, and the filter 832 is disposed downstream of the temperature regulator 833. Furthermore, various sensors may be disposed in the third feed pipe 83. For example, a pressure sensor 834 that detects a pressure of the purified fluid fed through the third feed pipe 83, and a temperature sensor 835 that detects the temperature of the purified fluid fed through the third feed pipe 83 may be disposed in the third feed pipe 83. In the example of the drawing, the pressure sensor 834 is disposed in the vicinity downstream of the supplying feed pump 831, and the temperature sensor 835 is disposed in the vicinity downstream of the temperature regulator 833.

### 3-2. Operations

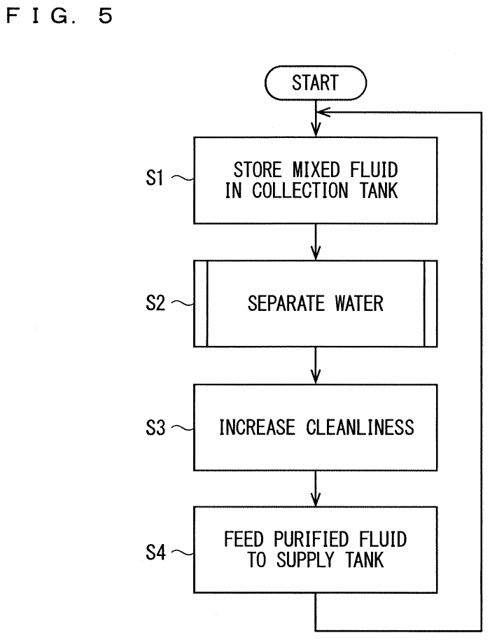

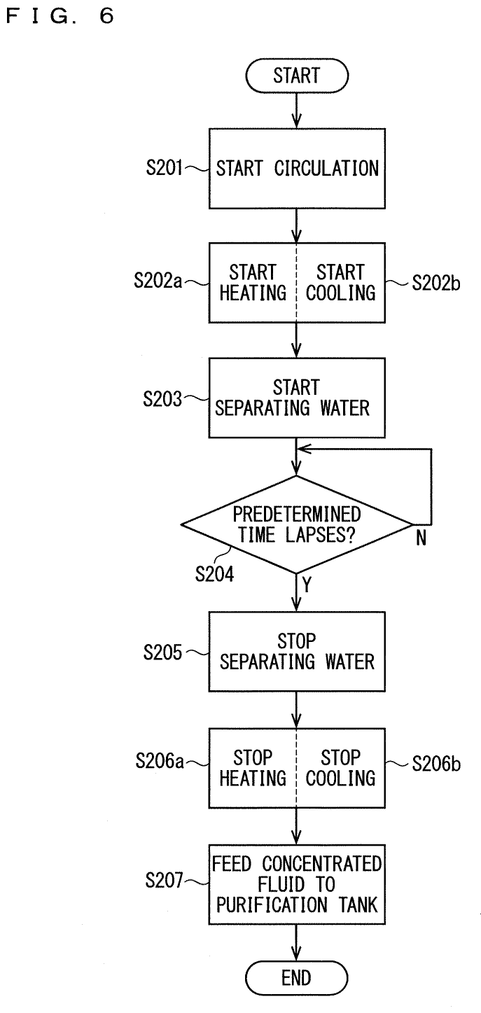

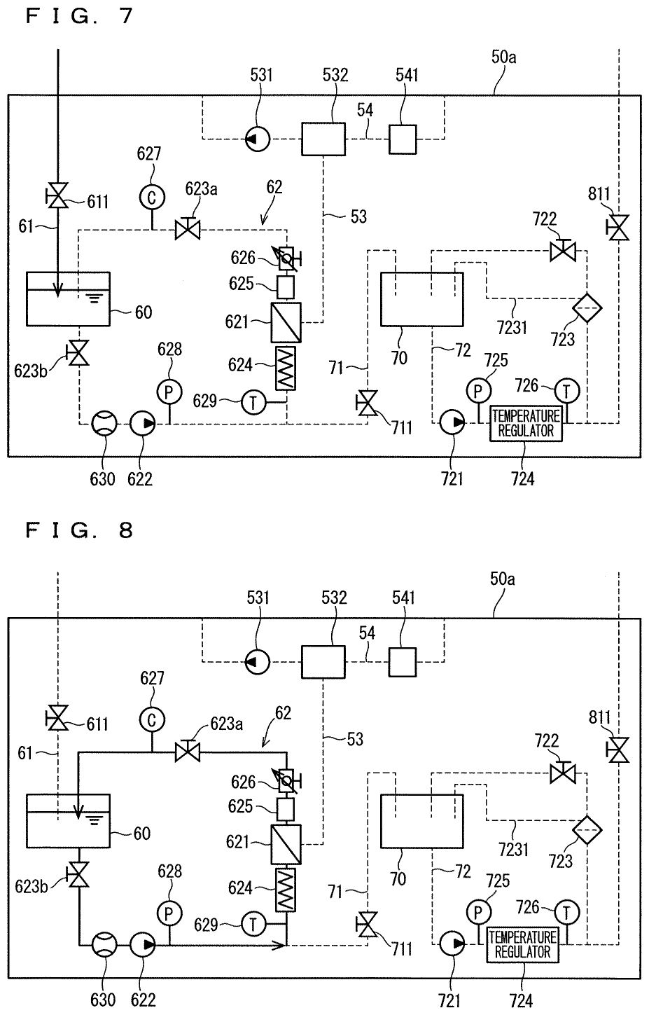

The procedure to be performed by the organic solvent collector 5 will be described with reference to FIGS. 5 to 12. FIG. 5 illustrates an example procedure to be performed by the organic solvent collector 5. FIG. 6 illustrates an example procedure for separating water from a mixed fluid. FIGS. 7 to 12 schematically illustrate a state of the organic solvent collector 5 in each step. In FIGS. 7 to 12, a solid line indicates a pipe through which a fluid flows, and a dashed line indicates a pipe through which a fluid does not flow for convenience in description.

The operations of the organic solvent collector 5 are performed under control of the controller 6. In other words, the controller 6 controls, for example, pumps (the dewatering feed pump 622, the vacuum pump 531, the purifying feed pump 721, and the supplying feed pump 831), valves (the collection valve 611, the pair of open/close valves 623a and 623b, the first feed valve 711, the open/close valve 722, the second feed valve 811, and the new liquid valve 822), the heater 624, the cooler 625, the pressure reducer 626, the condenser 532, the decomposer 541, the temperature regulators 724 and 833, based on information input from sensors (the concentration sensor 627, the pressure sensors 628, 725, and 834, the temperature sensors 629, 726, and 835, and the flow rate sensor 630), so that the organic solvent collector 5 proceeds with a series of the operations.

### Step S1

First, the collection valve 611 is opened with the collection tank 60 being empty. Then, the liquid collected by the cups 42 in the organic solvent supplying step and the spin drying step is guided by the collection pipe 61, and flows into the collection tank 60. Consequently, the collection tank 60 stores the mixed fluid containing the water supplied to the substrate W and then collected and the IPA supplied to the substrate W and then collected (FIG. 7) (a storing step). When the collection tank 60 stores a predetermined quantity of the mixed fluid, the collection valve 611 is closed.

### Step S2

Then, a process of separating water from the mixed fluid stored in the collection tank 60 is performed. This process will be specifically described with reference to FIGS. 6 and 8 to 10.

First, the pair of open/close valves 623a and 623b is opened, and the dewatering feed pump 622 feeds the mixed fluid at the circulation pressure. This allows the mixed fluid stored in the collection tank 60 to circulate through the dewatering circulation pipe 62 (Step S201: a circulating step) (FIG. 8).

Next, heating the mixed fluid is started (Step S202a: a heating step). Specifically, the heater 624 heats the mixed fluid circulating through the dewatering circulation pipe 62 to the heating temperature T1 higher than or equal to the boiling point of water. Furthermore, cooling the mixed fluid is started simultaneously when heating the mixed fluid is started (Step S202b: a cooling step). Specifically, the cooler 625 cools the mixed fluid circulating through the dewatering circulation pipe 62 to the cooling temperature T2 lower than the boiling point of IPA. By the heating and the cooling of the mixed fluid, the mixed fluid circulates through the dewatering circulation pipe 62 while changing the state. In other words, in this state, the mixed fluid circulating through the dewatering circulation pipe 62 is in the vapor state while flowing through the first piping portion 62a, and is in the liquid state while flowing through the second piping portion 62b.

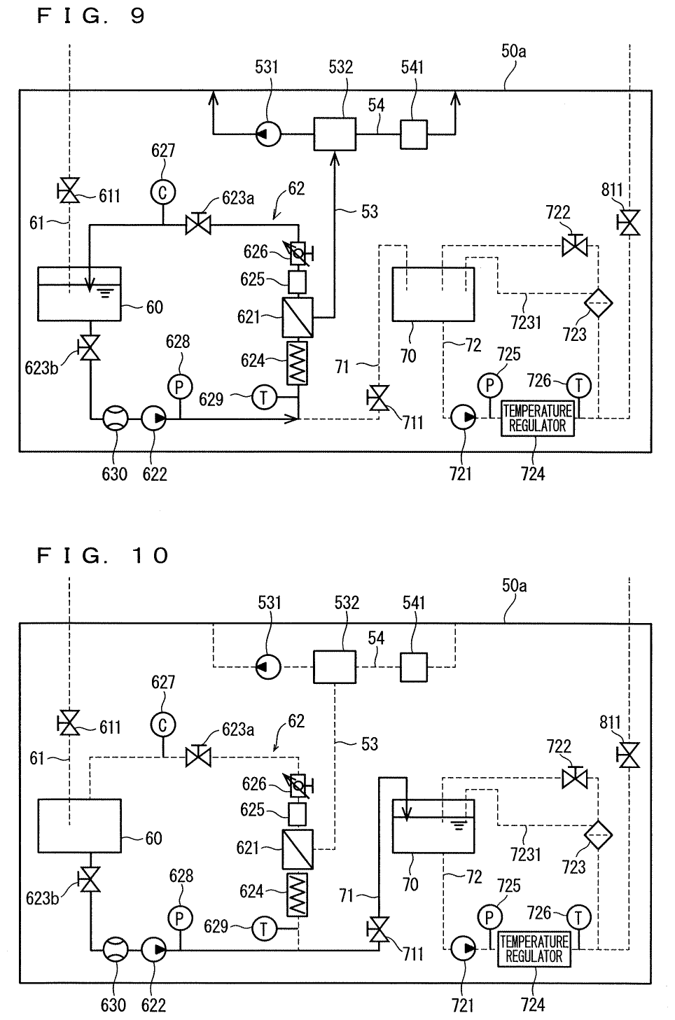

Then, the vacuum pump 531 starts to operate while the mixed fluid continues to be heated and cooled. Once the vacuum pump 531 operates, the pressure in the separation space V2 is reduced to provide a pressure difference between the cell internal space V1 and the separation space V2. This pressure difference allows water contained in the mixed fluid flowing into the cell internal space V1 to pass through the separation membrane 51, reach the separation space V2, and flow into the separation pipe 53. In other words, when the mixed fluid circulating through the dewatering circulation pipe 62 passes through the dewaterer 621, water contained in the mixed fluid is separated (Step S203: a separation step) (FIG. 9). Here, the mixed fluid flowing into the dewaterer 621 is heated to be in the vapor state (i.e., water and IPA contained in the mixed fluid are both in the vapor state). The water contained in the mixed fluid flowing into the dewaterer 621 is in the vapor state, which allows the water to be efficiently separated from the mixed fluid.

Then, a state where the vacuum pump 531 is operating is continued only for a predetermined time. During this time, the mixed fluid continues to be heated and cooled. Meanwhile, the mixed fluid circulating through the dewatering circulation pipe 62 repeatedly passes through the dewaterer 621, which increases the concentration of IPA in the mixed fluid. Here, the time required to sufficiently increase the concentration of IPA in the mixed fluid stored in the collection tank 60 (high enough to supply the fluid to the substrate W), that is, the time required to obtain the concentrated fluid is determined in advance through, for example, measurement and calculation, and is defined as the predetermined time. Thus, after a lapse of the predetermined time since start of operating the vacuum pump 531, the concentrated fluid is stored in the collection tank 60. After a lapse of the predetermined time since start of operating the vacuum pump 531 (YES in Step S204), the operation of the vacuum pump 531 is stopped. As a result, water separation in the dewaterer 621 is almost stopped (Step S205). Furthermore, heating the mixed fluid is stopped (Step S206a), and cooling the mixed fluid is stopped (Step S206b).

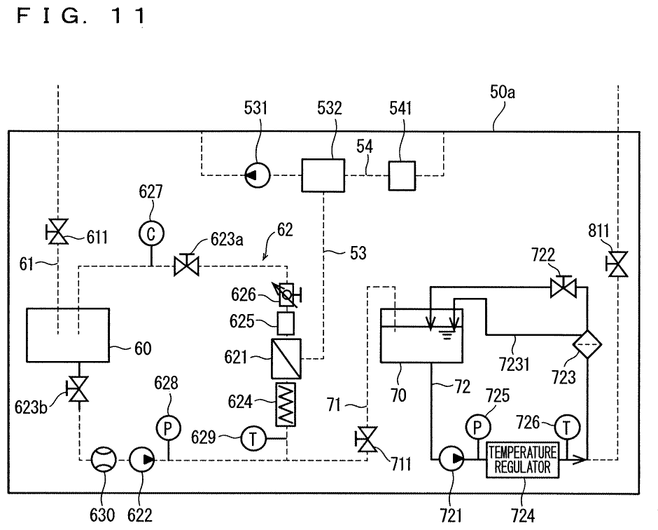

Then, the first feed valve 711 is opened. This allows the concentrated fluid stored in the collection tank 60 to be fed to the purification tank 70 through the first feed pipe 71. Thus, the concentrated fluid is stored in the purification tank 70 (Step S207) (FIG. 10). When the total quantity of the concentrated fluid stored in the collection tank 60 is fed to the purification tank 70, the first feed valve 711 is closed.

### Step S3

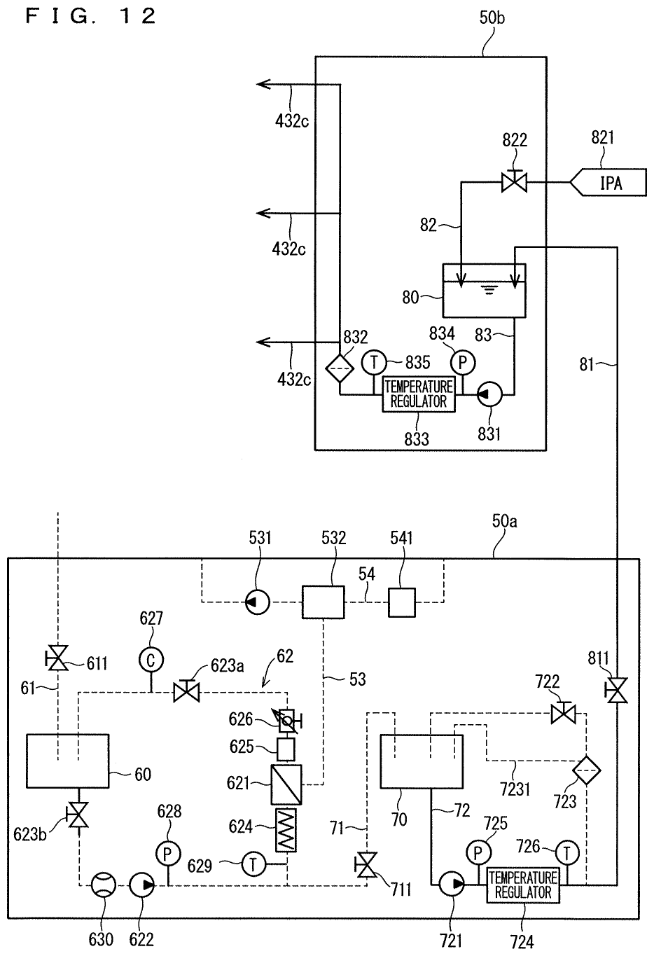

Next, a process of increasing the cleanliness of the concentrated fluid stored in the purification tank 70 is performed. Specifically, the open/close valve 722 is opened, and the purifying feed pump 721 feeds the concentrated fluid at the pressure necessary for circulation. This allows the concentrated fluid stored in the purification tank 70 to circulate through the purifying circulation pipe 72 (FIG. 11). This state is continued only for a predetermined time. Meanwhile, the concentrated fluid circulating through the purifying circulation pipe 72 repeatedly passes through the filter 723, which increases the cleanliness of the concentrated fluid. Here, the time required to sufficiently increase the cleanliness of the concentrated fluid circulating through the purifying circulation pipe 72 (high enough to supply the fluid to the substrate W), that is, the time required to obtain the purified fluid is determined in advance through, for example, measurement and calculation, and is defined as the predetermined time. Thus, after a lapse of the predetermined time since start of the circulation, the purified fluid is stored in the purification tank 70. After a lapse of the predetermined time since start of the circulation, the open/close valve 722 is closed.

### Step S4

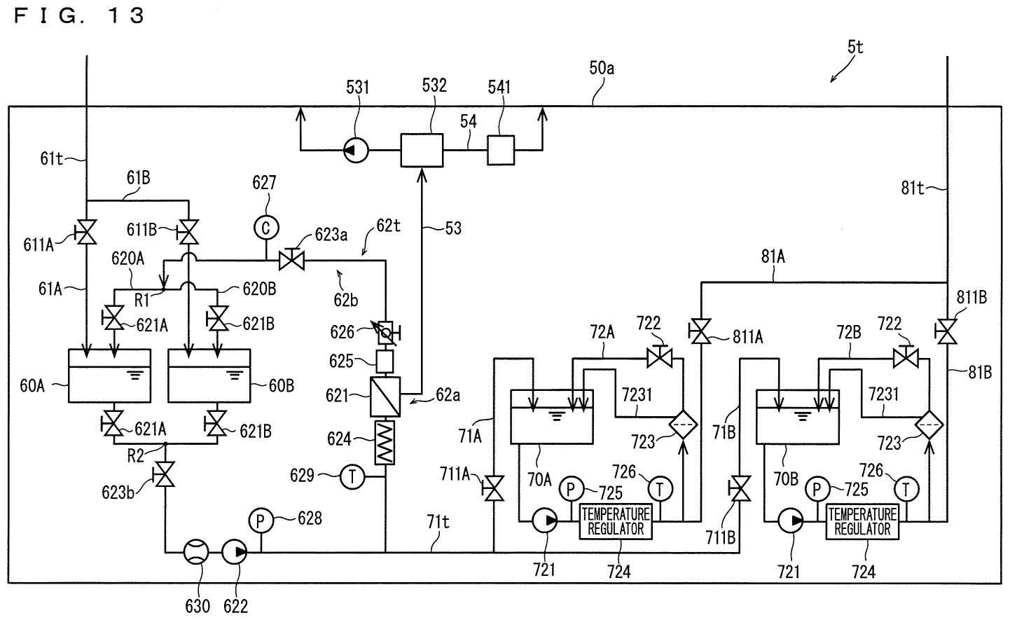

Next, the second feed valve 811 is opened. This allows the purified fluid in the purification tank 70 to be fed to the supply tank 80 through the second feed pipe 81. Thus, the purified fluid is stored in the supply tank 80 (FIG. 12). For example, when the total quantity of the purified fluid in the purification tank 70 is fed to the supply tank 80, the second feed valve 811 is closed. Then, once the organic solvent valves 431c are opened, the purified fluid stored in the supply tank 80 is fed by the supplying feed pump 831 to the organic solvent nozzles 43c side, and is discharged from the organic solvent nozzles 43c. In other words, the purified fluid is supplied to the substrates W. At some midpoint of the passage through the third feed pipe 83, the purified fluid may pass through the filter 832 to increase the cleanliness, or the temperature of the purified fluid may be regulated by the temperature regulator 833 as necessary. Furthermore, when the quantity of the purified fluid stored in the supply tank 80 is less than a predetermined quantity, the new liquid valve 822 may be opened to refill unused IPA in the supply tank 80.

In the organic solvent collector 5, the aforementioned series of processes (Steps S1 to S4) is repeated. However, a process in next Step S1 may be performed prior to the end of the process in Step S4 (e.g., at the completion of the process in Step S3).

### 4. ADVANTAGES

The substrate processing apparatus according to the embodiment above includes: a rinse liquid supply nozzle (the rinse liquid nozzle 43b) that supplies the substrate W with a rinse liquid containing water; an organic solvent supply nozzle (the organic solvent nozzle 43c) that supplies an organic solvent (e.g., IPA) to the substrate W; the collection tank 60 that stores a mixed fluid containing the water supplied to the substrate W and then collected and the organic solvent supplied to the substrate W and then collected; a circulation pipe (the dewatering circulation pipe 62) connected to the collection tank 60; the dewaterer 621 disposed in the dewatering circulation pipe 62 and including the separation membrane 51 that allows the water to pass through and does not allow the organic solvent to pass through; a pump (the dewatering feed pump 622) disposed in the dewatering circulation pipe 62; and the heater 624 disposed downstream of the collection tank 60 and upstream of the dewaterer 621 in the dewatering circulation pipe 62, the heater 624 heating the mixed fluid to a boiling point of the water or higher. This structure allows water contained in the mixed fluid to flow into the dewaterer 621 in the vapor state. This can enhance the separation efficiency using the separation membrane 51.

The substrate processing apparatus 100 according to the embodiment above includes the cooler 625 disposed downstream of the dewaterer 621 and upstream of the collection tank 60 in the dewatering circulation pipe 62. This structure can reduce the pressure of the mixed fluid by cooling the heated mixed fluid using the cooler 625. The mixed fluid circulating through the dewatering circulation pipe 62 is subjected to resistance when passing through the cooler 625. Thus, the mixed fluid in the vapor state tends to remain downstream of the cooler 625 (i.e., the first piping portion 62a). This allows the mixed fluid to fully come in contact with the separation membrane 51 to further enhance the separation efficiency using the separation membrane 51.

In the embodiment above, the cooler 625 cools the mixed fluid to a temperature lower than a boiling point of an organic solvent (e.g., IPA) and higher than a room temperature. This structure can sufficiently reduce the pressure of the mixed fluid, since IPA contained in the mixed fluid returns from the vapor state to the liquid state by cooling with the cooler 625. While the cooler 625 cools the mixed fluid merely to a temperature higher than a room temperature, the loads of the heater 624 and the cooler 625 are both reduced. As a result, for example, the heater 624 and the cooler 625 can be downsized.

In the embodiment above, the circulation pipe 62 includes the first pipe (the first piping portion 62a) downstream of the heater 624 and upstream of the cooler 625 and the second pipe (the second piping portion 62b) downstream of the cooler 625 and upstream of the heater 624, and the pressure resistance of the second pipe (the second piping portion 62b) is lower than that of the first pipe (the first piping portion 62a). This structure can make the apparatus more compact than that when the entire dewatering circulation pipe 62 has relatively high pressure resistance.

Furthermore, the substrate processing apparatus 100 according to the embodiment above includes the pressure reducer 626 that is disposed in the dewatering circulation pipe 62 and reduces the pressure of the mixed fluid cooled by the cooler 625. This structure allows further reduction of the pressure of the mixed fluid which has been reduced by the cooler 625 using the pressure reducer 626. Thus, the pressure applied to a piping portion (a pipe) downstream of the pressure reducer 626 in the second piping portion 62b, and the devices disposed in the piping portion can be sufficiently reduced.

Furthermore, the substrate processing apparatus 100 according to the embodiment above includes: the purification tank 70 connected to the collection tank 60 through a feed pipe (the first feed pipe 71) and storing a concentrated fluid obtained by separating water from the mixed fluid; and the filter 723 disposed in a pipe (the purifying circulation pipe 72) connected to the purification tank 70 and capturing a removal target substance contained in the concentrated fluid flowing through the purifying circulation pipe 72. This structure can increase the cleanliness of the concentrated fluid obtained by separating water from the mixed fluid, by removing the removal target substance from the concentrated fluid.

In the embodiment above, the concentrated fluid stored in the purification tank 70 is fed to the organic solvent nozzles 43c through the filter 723, and is supplied to the substrates W. In other words, after the cleanliness of the concentrated fluid obtained by separating water from the mixed fluid containing the water supplied to the substrate W and then collected and the organic solvent supplied to the substrate W and then collected is increased, the concentrated fluid is again supplied to the substrates W. Thus, the amounts of the organic solvent to be used and to be discharged can be reduced (saving liquid). IPA is a volatile organic compound (VOC), so reduction of the amounts of IPA to be used and to be discharged can mitigate the environmental load.

### 5. MODIFICATIONS

The structure and operations of the substrate processing apparatus 100 according to the embodiment above can be appropriately modified. In the following description, the same reference numerals are assigned to the same elements described in the embodiment above, and the description thereof will be omitted.

### 5-1. First Modification

The structure of an organic solvent collector 5t according to the first modification will be described with reference to FIG. 13. FIG. 13 schematically illustrates an example of the organic solvent collector 5t.

The organic solvent collector 5t includes a plurality of (two in the example of the drawing) collection tanks 60A and 60B, a plurality of (two in the example of the drawing) purification tanks 70A and 70B, and the supply tank 80 (see FIG. 3).

The collection tanks 60A and 60B are connected to the cups 42 through a collection pipe 61t. In other words, one end of the collection pipe 61t branches off, so that an end of a branched portion 61A is connected to the first collection tank 60A, and an end of a branched portion 61B is connected to the second collection tank 60B. The other end of the collection pipe 61t is connected to the cups 42 (specifically, the cup-side collecting pipes 424 connected to the cups 42). A collection valve 611A and a collection valve 611B are disposed in the branched portion 61A and the branched portion 61B, respectively. Once the collection valve 611A is opened, the liquid collected by the cups 42 in the organic solvent supplying step and the spin drying step is guided by the collection pipe 61t, and flows into and is stored by the first collection tank 60A. In other words, the mixed fluid is stored in the first collection tank 60A. Similarly, once the collection valve 611B is opened, the liquid collected by the cups 42 in the organic solvent supplying step and the spin drying step is guided by the collection pipe 61t, and flows into and is stored by the second collection tank 60B. In other words, the mixed fluid is stored in the second collection tank 60B.

A circulation pipe (a dewatering circulation pipe) 62t is connected to the collection tanks 60A and 60B. A branching position R1 and a merging position R2 are defined in the dewatering circulation pipe 62t. A plurality of branch pipes 620A and 620B (as many as the collection tanks 60A and 60B) are provided between the branching position R1 and the merging position R2. Furthermore, the collection tanks 60A and 60B are disposed in the branch pipes 620A and 620B, respectively. In other words, the one branch pipe 620A is provided with the first collection tank 60A, and the other branch pipe 620B is provided with the second collection tank 60B. Furthermore, a pair of first valves 621A is disposed in the branch pipe 620A, and the first collection tank 60A is sandwiched between the pair of first valves 621A. A pair of second valves 621B is disposed in the other branch pipe 620B, and the second collection tank 60B is sandwiched between the pair of second valves 621B. Once the pair of first valves 621A is opened and the pair of second valves 621B is closed, a circulation path is formed in which the mixed fluid stored in the first collection tank 60A circulates by flowing out of the first collection tank 60A and returning to the first collection tank 60A again. Conversely, once the pair of first valves 621A is closed and the pair of second valves 621B is opened, a circulation path is formed in which the mixed fluid stored in the second collection tank 60B circulates by flowing out of the second collection tank 60B and returning to the second collection tank 60B again.

Similarly to the embodiment above, the dewaterer 621, the dewatering feed pump 622, the pair of open/close valves 623a and 623b, the heater 624, the cooler 625, the pressure reducer 626, and the various sensors 627, 628, 629, and 630 are disposed in the dewatering circulation pipe 62t. These parts are disposed upstream of the branching position R1, and downstream of the merging position R2.

Similarly to the embodiment above, the heater 624 heats the mixed fluid to the heating temperature T1 higher than or equal to the boiling point of water. Furthermore, the cooler 625 cools the mixed fluid to the cooling temperature T2 lower than the boiling point of IPA. Thus, the mixed fluid circulating through the dewatering circulation pipe 62t is in the vapor state while flowing through the first piping portion 62a that is downstream of the heater 624 and upstream of the cooler 625. And the mixed fluid circulating through the dewatering circulation pipe 62t is in the liquid state while flowing through the second piping portion 62b that is downstream of the cooler 625 and upstream of the heater 624, similarly to the embodiment above. Thus, the first piping portion 62a, the devices disposed in the first piping portion 62a (e.g., the dewaterer 621), the heater 624, and the cooler 625 have pressure resistance enough to withstand the pressure of the mixed fluid in the vapor state, and have heat resistance that can withstand the heating temperature T1, similarly to the embodiment above. In contrast, the second piping portion 62b and the devices disposed in the second piping portion 62b (e.g., the first collection tank 60A, the second collection tank 60B, the dewatering feed pump 622, and the pair of open/close valves 623a and 623b) need not have pressure resistance enough to withstand the pressure of the mixed fluid in the vapor state and have heat resistance that can withstand the heating temperature T1. For example, the first collection tank 60A and the second collection tank 60B are atmospheric pressure tanks.

The purification tanks 70A and 70B are connected to the collection tanks 60A and 60B through a first feed pipe 71t and the dewatering circulation pipe 62t. In other words, one end of the first feed pipe 71t branches off, so that an end of a branched portion 71A is connected to the first purification tank 70A, and an end of a branched portion 71B is connected to the second purification tank 70B. The other end of the first feed pipe 71t is connected to the second piping portion 62b of the dewatering circulation pipe 62t. A first feed valve 711A and a first feed valve 711B are disposed in the branched portion 71A and the branched portion 71B, respectively. When the first collection tank 60A or the second collection tank 60B stores the concentrated fluid, once the first feed valve 711A on the first purification tank 70A side is opened, the concentrated fluid is guided by the first feed pipe 71t, and flows into and is stored by the first purification tank 70A. Similarly, when the first collection tank 60A or the second collection tank 60B stores the concentrated fluid, once the first feed valve 711B on the second purification tank 70B side is opened, the concentrated fluid is guided by the first feed pipe 71t, and flows into and is stored by the second purification tank 70B.

Circulation pipes (purifying circulation pipes) 72A and 72B are connected to the first purification tank 70A and the second purification tank 70B, respectively. Similarly to the purifying circulation pipe 72 according to the embodiment above, the purifying feed pump 721, the open/close valve 722, the filter 723, the temperature regulator 724, and the various sensors 725 and 726 are disposed in each of the purifying circulation pipes 72A and 72B.

The first purification tank 70A and the second purification tank 70B are connected to the supply tank 80 (FIG. 3) through the purifying circulation pipes 72A and 72B, respectively, and through a second feed pipe 81t. In other words, one end of the second feed pipe 81t branches off, so that an end of a branched portion 81A is connected to the purifying circulation pipe 72A on the first purification tank 70A side, and an end of a branched portion 81B is connected to the purifying circulation pipe 72B on the second purification tank 70B side. The other end of the second feed pipe 81t is connected to the supply tank 80. A second feed valve 811A and a second feed valve 811B are disposed in the branched portion 81A and the branched portion 81B, respectively. When the first purification tank 70A stores the purified fluid, once the second feed valve 811A on the first purification tank 70A side is opened, the purified fluid in the first purification tank 70A is guided by the second feed pipe 81t, and flows into and is stored by the supply tank 80. Similarly, when the second purification tank 70B stores the purified fluid, once the second feed valve 811B on the second purification tank 70B side is opened, the purified fluid in the second purification tank 70B is guided by the second feed pipe 81t, and flows into and is stored by the supply tank 80.

The organic solvent collector 5t also performs the series of processes (Steps S1 to S4 in FIG. 5) similarly to the embodiment above.

In other words, similarly to the embodiment above, in the organic solvent collector 5t, the liquid collected by the cups 42 is first fed to one of the collection tanks (e.g., the first collection tank 60A), and the mixed fluid is stored by the first collection tank 60A (Step S1). Then, a process of separating water from the mixed fluid stored in the first collection tank 60A is performed (Step S2). However, in the organic solvent collector 5t, in parallel with this process, the liquid collected by the cups 42 is fed to the other collection tank (the second collection tank 60B), and the mixed fluid is stored by the second collection tank 60B. In other words, after the liquid collected by the cups 42 is fed to the first collection tank 60A, the liquid collected by the cups 42 is fed to the second collection tank 60B without waiting for emptying the first collection tank 60A (i.e., without waiting for the end of the process of separating water from the mixed fluid stored in the first collection tank 60A).

Similarly to the embodiment above, in the organic solvent collector 5t, the concentrated fluid obtained by separating water from the mixed fluid is fed from the first collection tank 60A or the second collection tank 60B to the first purification tank 70A or the second purification tank 70B, and is stored by the first purification tank 70A or the second purification tank 70B. Once the concentrated fluid is stored by each of the first purification tank 70A and the second purification tank 70B, the process of increasing the cleanliness of the concentrated fluid is performed (Step S3), and the resulting purified fluid is fed to the supply tank 80 (Step S4). Since the plurality of purification tanks 70A and 70B are provided, even when the process of increasing the cleanliness of the concentrated fluid is performed in the one purification tank 70A, the concentrated fluid can be fed to the other purification tank 70B.

Since the organic solvent collector 5t includes the plurality of collection tanks 60A and 60B, switching between the collection tanks 60A and 60B that are feeding destinations can feed the liquid collected by the cups 42 (i.e., the water supplied to the substrate W and then collected and the organic solvent supplied to the substrate W and then collected) without interruption. Furthermore, since the organic solvent collector 5t includes the plurality of purification tanks 70A and 70B, switching between the purification tanks 70A and 70B that are feeding destinations can feed the concentrated fluid obtained by separating water from the mixed fluid without interruption. These can shorten the cycle time from collecting the organic solvent supplied to the substrate W until supplying the organic solvent again to the substrate W. Consequently, the amounts of the organic solvent to be used and to be discharged can be effectively reduced.

### 5-2. Second Modification

In the organic solvent collector 5 according to the embodiment above, the dewaterer 621 may be disposed in an attitude and an orientation such that the cells 512 extend in the vertical direction and the inlet 521 is disposed at a vertical bottom (i.e., the first outlet 522 is disposed at a vertical top). Here, the mixed fluid flowing through the dewatering circulation pipe 62 flows into the cells 512 from an opening at a vertical bottom of the cells 512.

In this modification, the mixed fluid flowing from the dewatering circulation pipe 62 into the cells 512 which extend in the vertical direction flows from the bottom to the top inside the cells 512 (the cell internal space V1). Thus, for example, even when a part of the mixed fluid flowing into the cell internal space V1 is condensed into a liquid (e.g., droplets) at some midpoint of the passage through the cell internal space V1, the mixed fluid sufficiently remains in the cell internal space V1 under gravity, and fully comes in contact with the separation membrane 51. This increases the probability of separating water contained in the liquid. In other words, the separation efficiency is further enhanced. In this modification, the pressure head makes the pressure of the mixed fluid at the secondary side of the dewaterer 621 lower than that at the primary side. In other words, the pressure of the mixed fluid that has passed through the dewaterer 621 can be reduced.

### 5-3. Third Modification

When the dewaterer 621 is disposed in an attitude such that the cells 512 extend in the vertical direction as in the organic solvent collector 5 according to the second modification, the dewaterer 621 and the heater 624 may be aligned in the vertical direction. Specifically, for example, when the dewaterer 621 is disposed in an attitude such that the cells 512 extend in the vertical direction, a pipe (a piping portion) (hereinafter referred to as a vertical piping portion) extending in the vertical direction may be disposed (included) in a connection portion to the inlet 521 and its vicinity in the dewatering circulation pipe 62, and the heater 624 may be disposed in this vertical piping portion. For example, the heater 624 that includes a jacket heater may be disposed to cover at least the perimeter of the vertical piping portion. Disposing the heater 624 in the vertical piping portion reduces the heat loss occurring until the mixed fluid heated by the heater 624 flows into the dewaterer 621. Moreover, the load of the heater 624 is reduced.

### 5-4. Other Modifications

In the embodiment above, reducing the heat loss occurring until the mixed fluid heated by the heater 624 flows into the dewaterer 621 is effective at reducing the load of the heater 624. A separation distance between the heater 624 and the dewaterer 621 is preferably shorter to reduce this heat loss. For example, the heater 624 is preferably disposed at a position at which the separation distance with the dewaterer 621 has the smallest value allowable in design. It is preferred not to dispose other devices between the heater 624 and the dewaterer 621 to reduce the separation distance between the heater 624 and the dewaterer 621.

In the embodiment above, the first piping portion 62a requires relatively high pressure resistance and relatively high heat resistance. Thus, reducing a proportion of the first piping portion 62a to the dewatering circulation pipe 62 in length is preferred to make the apparatus more compact. Reducing a separation distance between the heater 624 and the cooler 625 is preferred to fulfill this requirement. In view of this point, the heater 624 is preferably disposed at a position at which the separation distance with the dewaterer 621 has the smallest value allowable in design as described above. Furthermore, the cooler 625 is preferably disposed at a position at which the separation distance with the dewaterer 621 has the smallest value allowable in design. It is preferred not to dispose other devices between the cooler 625 and the dewaterer 621 to reduce the separation distance between the cooler 625 and the dewaterer 621.

In the embodiment above, disposing the pressure reducer 626 in the dewatering circulation pipe 62 reduces the pressure applied to a piping portion (a pipe) downstream of the pressure reducer 626 and the devices disposed in the piping portion relative to the pressure applied to a piping portion (a pipe) upstream of the pressure reducer 626 and the devices disposed in the piping portion. To effectively mitigate the load on, for example, the pipe, it is preferred to dispose the pressure reducer 626 upstream as much as possible and thus to reduce a separation distance between the pressure reducer 626 and the cooler 625. For example, the pressure reducer 626 is preferably disposed at a position at which the separation distance with the cooler 625 has the smallest value allowable in design. It is preferred not to dispose other devices between the pressure reducer 626 and the cooler 625 to reduce the separation distance between the pressure reducer 626 and the cooler 625. The pressure resistance of a piping portion (a pipe) downstream of the pressure reducer 626 in the second piping portion 62b and the devices disposed in the piping portion may be lower than that of a piping portion (a pipe) upstream of the pressure reducer 626 in the second piping portion 62b and the devices disposed in the piping portion.

In the organic solvent collector 5 according to the embodiment above, one or both of the pressure reducer 626 and the cooler 625 may be omitted. For example, when the second piping portion 62b and the devices disposed in the second piping portion 62b have pressure resistance enough to withstand the pressure of the mixed fluid in the vapor state and have heat resistance that can withstand the heating temperature T1, the cooler 625 and the pressure reducer 626 may be omitted.

In the organic solvent collector 5 according to the embodiment, above one tank may be shared as the collection tank 60 and the purification tank 70. Specifically, for example, the dewatering circulation pipe 62 and the purifying circulation pipe 72 may be connected to one tank (a collection purification tank). Here, a mixed fluid stored in the collection purification tank may be first circulated through the dewatering circulation pipe 62 to obtain a concentrated fluid. Then, the obtained concentrated fluid may be circulated through the purifying circulation pipe 72 to obtain a purified fluid.

In the organic solvent collector 5 according to the embodiment above, a filter may be disposed in the dewatering circulation pipe 62. In other words, a removal target substance may be removed from the mixed fluid circulating through the dewatering circulation pipe 62 while water is separated from the mixed fluid. Here, the purification tank 70 may be omitted, and the collection tank 60 may be directly connected to the supply tank 80 (not through the purification tank 70).

In the organic solvent collector 5 according to the embodiment above, the structure of the dewaterer 621 can be appropriately modified. For example, the separation membrane 51 included in the dewaterer 621 is not limited to a zeolite membrane. The separation membrane 51 may be, for example, an organic separation membrane. The organic separation membrane is, for example, an organic membrane made of polyvinyl alcohol, chitosan, or polyimide. Alternatively, the separation membrane 51 may be a carbon nanotube (CNT) separation membrane. The CNT separation membrane is, for example, a membrane obtained by adding carbon nanotube to a membrane made of, for example, polyamide. Alternatively, the separation membrane 51 may be made of a two-dimensional material. The two-dimensional material is a material consisting of an atomic monolayer, specifically, for example, molybdenum sulfide (MoS₂), and a composite atomic layer compound containing an early transition metal (titanium, vanadium, etc.) and a light element (carbon or nitrogen). Alternatively, the separation membrane 51 may be made of a metal-organic framework (MOF) material, or a carbon material (e.g., graphene, graphene oxide, etc.).

In the substrate processing apparatus 100 according to the embodiment above, the processing units 4 from and to which the organic solvent collector 5 collects and supplies an organic solvent need not be the processing units 4 included in the same tower. In other words, the organic solvent collector 5 may collect and supply an organic solvent from and to at least one of the processing units 4 arbitrarily chosen. Furthermore, the processing unit 4 from which the organic solvent collector 5 collects an organic solvent may be different from the processing unit 4 to which the organic solvent collector 5 supplies an organic solvent.

In the substrate processing apparatus 100 according to the embodiment above, an organic solvent is not limited to IPA. The organic solvent may be, for example, at least one of hydrofluoroethers (HFE), methanol, ethanol, acetone, or trans-1,2-dichloroethylene. The organic solvent need not consist of a single component, but may be a liquid obtained by mixing a plurality of components.

In the substrate processing apparatus 100 according to the embodiment above, a rinse liquid may be of a variety of types which contain water. The rinse liquid may be, for example, one of carbonated water, electrolytic ionized water, hydrogen water, ozonized water, or a diluted hydrochloric acid (for example, a hydrochloric acid having a dilution concentration of 10 to 100 ppm).

The substrate W to be processed by the substrate processing apparatus 100 according to the embodiment above need not always be a semiconductor substrate. Examples of the substrate W to be processed may include a photolithographic mask glass substrate, a liquid crystal display glass substrate, a plasma display glass substrate, a field-emission display (FED) substrate, an optical disk substrate, a magnetic disk substrate, and a magneto-optical disk substrate. The substrate W to be processed need not be completely circular but may have a shaped portion such as a notch and an orientation flat.

Although the substrate processing apparatus and the substrate processing method are described above in detail, the description is in all aspects illustrative and does not restrict the substrate processing apparatus and the substrate processing method. Therefore, numerous modifications and variations that have not yet been exemplified are devised without departing from the scope of the present disclosure. The structures described in the embodiment and the modifications can be appropriately combined or omitted unless any contradiction occurs.

The present disclosure includes the following aspects.

The first aspect is a substrate processing apparatus including: a rinse liquid supply nozzle that supplies a substrate with a rinse liquid containing water; an organic solvent supply nozzle that supplies an organic solvent to the substrate; a collection tank that stores a mixed fluid containing the water supplied to the substrate and then collected and the organic solvent supplied to the substrate and then collected; a circulation pipe connected to the collection tank; a dewaterer disposed in the circulation pipe and including a separation membrane that allows the water to pass through and does not allow the organic solvent to pass through; a pump disposed in the circulation pipe; and a heater disposed downstream of the collection tank and upstream of the dewaterer in the circulation pipe, the heater heating the mixed fluid to a boiling point of the water or higher.

The second aspect is the substrate processing apparatus according to the first aspect, and includes a cooler disposed downstream of the dewaterer and upstream of the collection tank in the circulation pipe.

The third aspect is the substrate processing apparatus according to the second aspect, and the cooler cools the mixed fluid to a temperature lower than a boiling point of the organic solvent and higher than a room temperature.

The fourth aspect is the substrate processing apparatus according to the second or third aspect, and the circulation pipe includes a first pipe downstream of the heater and upstream of the cooler and a second pipe downstream of the cooler and upstream of the heater, and pressure resistance of the second pipe is lower than that of the first pipe.

The fifth aspect is the substrate processing apparatus according to any one of the second to fourth aspects, and includes a pressure reducer that is disposed in the circulation pipe and reduces a pressure of the mixed fluid cooled by the cooler.

The sixth aspect is the substrate processing apparatus according to any one of the first to fifth aspects, and includes: a purification tank connected to the collection tank through a feed pipe and storing a concentrated fluid obtained by separating the water from the mixed fluid; and a filter disposed in a pipe connected to the purification tank and capturing a removal target substance contained in the concentrated fluid flowing through the pipe.

The seventh aspect is the substrate processing apparatus according to the sixth aspect, and the concentrated fluid stored in the purification tank is fed to the organic solvent supply nozzle through the filter, and is supplied to the substrate.

The eighth aspect is the substrate processing apparatus according to any one of the first to seventh aspects, and the circulation pipe includes a plurality of branch pipes (branched portions) disposed between a branching position and a merging position, and the collection tank is disposed in each of the plurality of branch pipes (branched portions).

The ninth aspect is the substrate processing apparatus according to any one of the first to eighth aspects, and the dewaterer is disposed in an attitude such that a cell that forms a flow path of the mixed fluid in the separation membrane extends in a vertical direction, and the mixed fluid flowing through the circulation pipe flows into the cell from an opening at a vertical bottom of the cell.

The tenth aspect is the substrate processing apparatus according to the ninth aspect, and the dewaterer and the heater are aligned in the vertical direction.

The eleventh aspect is a substrate processing method and includes: supplying a substrate with a rinse liquid containing water; supplying an organic solvent to the substrate; storing, in a collection tank, a mixed fluid containing the water supplied to the substrate and then collected and the organic solvent supplied to the substrate and then collected; circulating the mixed fluid stored in the collection tank, through a circulation pipe connected to the collection tank; heating the mixed fluid to a boiling point of the water or higher, using a heater disposed in the circulation pipe; and causing the heated mixed fluid to flow into a dewaterer including a separation membrane that allows the water to pass through and does not allow the organic solvent to pass through, and separating the water from the mixed fluid, the dewaterer being disposed downstream of the heater and upstream of the collection tank in the circulation pipe.

Each of the first and eleventh aspects allows the water contained in the mixed fluid to flow into the dewaterer in the vapor state. This can enhance the separation efficiency using the separation membrane.

The second aspect can reduce the pressure of the mixed fluid by cooling the heated mixed fluid using the cooler.

The third aspect can sufficiently reduce the pressure of the mixed fluid, since the organic solvent contained in the mixed fluid returns from the vapor state to the liquid state by cooling with the cooler. While the cooler cools the mixed fluid merely to a temperature higher than a room temperature, the loads of the heater and the cooler are both reduced.

Since pressure resistance of a part of the circulation pipe (a second pipe (a second piping portion) downstream of the cooler and upstream of the heater) is lower than pressure resistance of another part of the circulation pipe (a first pipe (a first piping portion) downstream of the heater and upstream of the cooler), the fourth aspect can make the apparatus more compact than that when the entire circulation pipe has relatively high pressure resistance.

The fifth aspect allows further reduction of the pressure of the mixed fluid which has been reduced by the cooler using the pressure reducer.

The sixth aspect can increase the cleanliness of the concentrated fluid obtained by separating water from the mixed fluid, by removing a removal target substance from the concentrated fluid.

According to the seventh aspect, after the cleanliness of the concentrated fluid obtained by separating water from the mixed fluid that contains the water supplied to the substrate and then collected and the organic solvent supplied to the substrate and then collected is increased, the concentrated fluid is again supplied to the substrate. Thus, the amounts of the organic solvent to be used and to be discharged can be reduced.

According to the eighth aspect, since the plurality of collection tanks are disposed in the circulation pipe, the collection tank to be feed destinations can be switched, thereby enabling the water supplied to the substrate and then collected and the organic solvent supplied to the substrate and then collected to be fed without interruption.

According to the ninth aspect, the mixed fluid flowing from the circulation pipe into the cell extending in the vertical direction flows from the bottom to the top inside the cell. Thus, the mixed fluid flowing inside the cell sufficiently remains inside the cell, and fully comes in contact with the separation membrane. This further enhances the separation efficiency.

The tenth aspect reduces the heat loss occurring until the mixed fluid heated by the heater flows into the dewaterer. Moreover, the load of the heater is reduced.

While the disclosure has been shown and described in detail, the foregoing description is in all aspects illustrative and not restrictive. It is therefore understood that numerous modifications and variations can be devised.

What is claimed is:

1. A substrate processing apparatus, comprising:
a rinse liquid supply nozzle that supplies a substrate with a rinse liquid containing water;
an organic solvent supply nozzle that supplies an organic solvent to the substrate;
a collection tank that stores a mixed fluid containing the water supplied to the substrate and then collected and the organic solvent supplied to the substrate and then collected;
a circulation pipe connected to the collection tank;
a dewaterer disposed in the circulation pipe and including a separation membrane that allows the water to pass through and does not allow the organic solvent to pass through;
a pump disposed in the circulation pipe; and
a heater disposed downstream of the collection tank and upstream of the dewaterer in the circulation pipe, the heater heating the mixed fluid to a boiling point of the water or higher.

2. The substrate processing apparatus according to claim 1, further comprising
a cooler disposed downstream of the dewaterer and upstream of the collection tank in the circulation pipe.

3. The substrate processing apparatus according to claim 2,
wherein the cooler cools the mixed fluid to a temperature lower than a boiling point of the organic solvent and higher than a room temperature.

4. The substrate processing apparatus according to claim 2,
wherein the circulation pipe includes a first pipe downstream of the heater and upstream of the cooler and a second pipe downstream of the cooler and upstream of the heater, and pressure resistance of the second pipe is lower than that of the first pipe.

5. The substrate processing apparatus according to claim 2, further comprising
a pressure reducer that is disposed in the circulation pipe and reduces a pressure of the mixed fluid cooled by the cooler.

6. The substrate processing apparatus according to claim 1, further comprising:
a purification tank connected to the collection tank through a feed pipe and storing a concentrated fluid obtained by separating the water from the mixed fluid; and
a filter disposed in a pipe connected to the purification tank and capturing a removal target substance contained in the concentrated fluid flowing through the pipe.

7. The substrate processing apparatus according to claim 6,
wherein the concentrated fluid stored in the purification tank is fed to the organic solvent supply nozzle through the filter, and is supplied to the substrate.

8. The substrate processing apparatus according to claim 1,
wherein the circulation pipe includes a plurality of branch pipes disposed between a branching position and a merging position, and
the collection tank is disposed in each of the plurality of branch pipes.

9. The substrate processing apparatus according to claim 1,
wherein the dewaterer is disposed in an attitude such that a cell that forms a flow path of the mixed fluid in the separation membrane extends in a vertical direction, and
the mixed fluid flowing through the circulation pipe flows into the cell from an opening at a vertical bottom of the cell.

10. The substrate processing apparatus according to claim 9,
wherein the dewaterer and the heater are aligned in the vertical direction.

11. A substrate processing method, comprising:
supplying a substrate with a rinse liquid containing water;
supplying an organic solvent to the substrate;
storing, in a collection tank, a mixed fluid containing the water supplied to the substrate and then collected and the organic solvent supplied to the substrate and then collected;
circulating the mixed fluid stored in the collection tank, through a circulation pipe connected to the collection tank;
heating the mixed fluid to a boiling point of the water or higher, using a heater disposed in the circulation pipe; and
causing the heated mixed fluid to flow into a dewaterer including a separation membrane that allows the water to pass through and does not allow the organic solvent to pass through, and separating the water from the mixed fluid, the dewaterer being disposed downstream of the heater and upstream of the collection tank in the circulation pipe.
